(19) United States
(12) Patent Application Publication
(10) Pub. No.: US 2026/0173496 A1
(43) Pub. Date: Jun. 18, 2026

(54) METHODS FOR FORMING VIA CONTACT STRUCTURES TO ENABLE CONTACT MASK REDUCTION

(71) Applicant: Taiwan Semiconductor Manufacturing Co., Ltd., Hsinchu (TW)

(72) Inventors: Sheng-Tsung WANG, Hsinchu (TW); Meng-Huan JAO, Hsinchu (TW); Min-Hsuan LU, Hsinchu (TW); Chen-Luo CHENG, Hsinchu (TW); Huan-Chieh SU, Hsinchu (TW); Kuo-Cheng CHIANG, Hsinchu (TW); Chih-Hao WANG, Hsinchu (TW)

(73) Assignee: Taiwan Semiconductor Manufacturing Co., Ltd., Hsinchu (TW)

(21) Appl. No.: 19/217,902

(22) Filed: May 23, 2025

Related U.S. Application Data
(60) Provisional application No. 63/735,229, filed on Dec. 17, 2024.

(51) Int. Cl. H10D 84/01; H10D 30/00; H10D 64/23; H10D 64/27

(52) U.S. Cl. CPC H10D 84/0149; H10D 30/501; H10D 64/251; H10D 64/511

(57) ABSTRACT

A method for forming a semiconductor structure includes forming a plurality of nanostructures, forming a gate structure on the nanostructures, forming a source/drain feature adjacent to the gate structure, forming a source/drain contact feature on the source/drain feature, forming a dielectric layer on the gate structure and the source/drain contact feature, etching the dielectric layer to form a first opening on the gate structure and a second opening on the source/drain contact feature, forming a metal liner layer in the first opening and the second opening, removing portion of the metal liner layer to form metal liners on bottoms of the first opening and the second opening, and depositing a conductive material layer on the metal liners to fill the first opening and the second opening to form a first via contact feature in the first opening and a second via contact feature in the second opening.

### PRIORITY CLAIM AND CROSS-REFERENCE

This application claims the benefit of U.S. Provisional Ser. No. 63/735,229 filed Dec. 17, 2024, which is incorporated by reference herein in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. While scaling down can increase production efficiency and reduce costs, it also induces greater complexity in the processing and manufacturing of ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flowchart of a method for fabricating a gate-all-around (GAA) device, in accordance with some embodiments of the present disclosure.

FIGS. 2-25 illustrate various views of the GAA device during a fabrication process according to the method of FIG. 1, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In FET fabrication, a source/drain via contact (VD) is typically formed in the vertical direction to electrically couple source/drain contact structure to an upper-level interconnect structure. Similarly, a gate via contact (VG) extends vertically to establish an electrical connection between the metal gate and an upper-level interconnect structure. In some embodiments, the formation of these via contacts includes forming openings in a dielectric layer, filing the openings with a conductive material(s), and performing a planarization process, such as chemical mechanical polishing (CMP), to refine the conductive material(s).

In existing technologies, source/drain via contacts (VDs) and gate via contacts (VGs) are usually made from different metals, necessitating separate formation processes. As a result, different contact masks are required to define their respective formation areas and/or accommodate different metal depositions. However, as transistor dimensions continue to shrink, the spacing between the metal gate and the source/drain contact becomes increasingly limited. Misalignment between contact masks during separate etching processes can lead to unintended shorting between the gate and source/drain via contacts. Additionally, the additional steps required to separately form gate and source/drain via contacts contribute to increased manufacturing costs.

In embodiments of the present disclosure, the same metal is used to form both gate via contact features and the source/drain via contact features. As a result, the gate and source/drain via contact features can be formed simultaneously using the same masks or set of masks, which reduces the number of masks required and thereby lowers manufacturing costs.

The disclosed methods and structures can be applied to ICs having FinFETs, gate-all-around (GAA) transistors, or other types of transistors. GAA transistors refer to transistors having gate stacks (which include gate electrodes and gate dielectric) surrounding channel nanostructures, such as vertically-stacked horizontal nanowires or nanosheets.

The gate-all-around (GAA) transistor structures described below may be patterned by any suitable method. For example, the structures may be patterned using one or more photolithography processes, including double-patterning or multi-patterning processes.

Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structures.

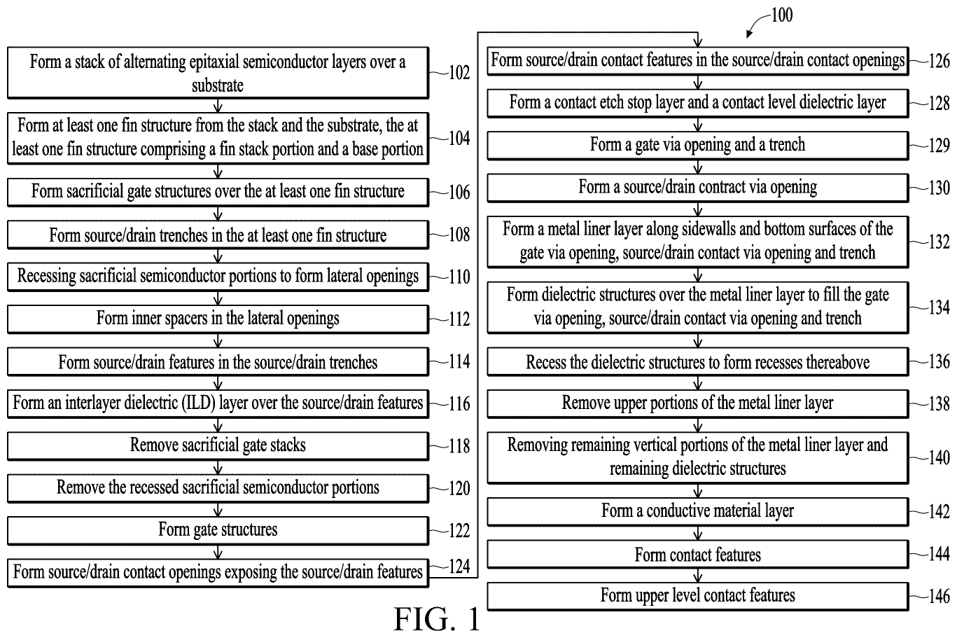

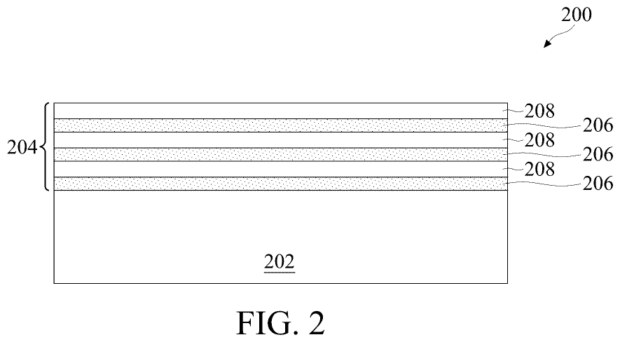

FIG. 1 is a flowchart of a method 100 of forming a GAA device 200, in accordance with some embodiments of the present disclosure. FIGS. 2-25 are various views of the GAA device 200 at various stages of the method 100, in accordance with some embodiments. Some embodiments of method 100 are described below in conjunction with FIGS. 2-25 with reference to the GAA device 200. The method 100 is merely an example and is not intended to limit the present disclosure beyond what is explicitly recited in the claims. Additional operations can be provided before, during, and after the method 100, and some operations described can be replaced, eliminated, or moved around for additional embodiments of the method.

Referring to FIGS. 1 and 2, the method 100 includes operation 102, where an initial structure of the GAA device 200 is provided. The initial structure includes a substrate 202 and a stack 204 of alternating epitaxial semiconductor layers over the substrate 202. FIG. 2 is a cross-sectional view of the GAA device 200 after forming the stack 204 of the alternating epitaxial semiconductor layers over the substrate 202.

The substrate 202 can be any suitable substrate and can be processed with various features. In some embodiments, the substrate 202 may be a semiconductor substrate, such as a silicon substrate. In some embodiments, the substrate 202 includes various layers, including conductive or insulating layers formed on a semiconductor substrate. The substrate 202 may include various doping configurations. For example, different doping profiles (e.g., n wells, p wells) may be formed on the substrate 202 in regions designed for different device types (e.g., n-type FETs, p-type FETs). The suitable doping may include ion implantation of dopants and/or diffusion processes. Even though not shown, the substrate 202 includes isolation features (e.g., shallow trench isolation (STI) features) interposing the regions providing different device types. The substrate 202 includes other semiconductors such as germanium or diamond. Alternatively, the substrate 202 includes a compound semiconductor such as silicon carbide (SiC), gallium arsenide, gallium phosphide, indium phosphide, indium arsenide, indium antimonide; an alloy semiconductor, such as SiGe, GaAsP, AlInAs, AlGaAs, GalnAs, GaInP, GaInAsP, and/or other suitable materials. Further, the substrate 202 may optionally include an epitaxial layer, may be strained for performance enhancement, may include a silicon-on-insulator structure, and/or may have other suitable enhancement features.

The stack 204 of alternating epitaxial semiconductor layers is blanketly deposited on the substrate 202. The stack 204 comprises alternating sacrificial semiconductor layers 206 and channel semiconductor layers 208, where a channel semiconductor layer 208 forms the topmost layer, and a sacrificial semiconductor layer 206 forms the bottommost layer. In some embodiments, the sacrificial semiconductor layers 206 include a first semiconductor material, and the channel semiconductor layers 208 include a second semiconductor material that is different from the first semiconductor material. The materials of sacrificial semiconductor layers 206 and channel semiconductor layers 208 may be chosen based on providing different etching selectivities. For example, in some embodiments, the first semiconductor material may comprise germanium (Ge) or silicon germanium (SiGe), whereas the second semiconductor material may comprise silicon (Si). In some alternative embodiments, the first semiconductor material includes SiGe having a first Ge content, and the second semiconductor material includes SiGe having a second Ge content lower than the first Ge content. In various embodiments, the sacrificial semiconductor layers 206 and the channel semiconductor layer 208 are substantially dopant-free (i.e., having an extrinsic dopant concentration less than about 1×10¹⁷ cm⁻³).

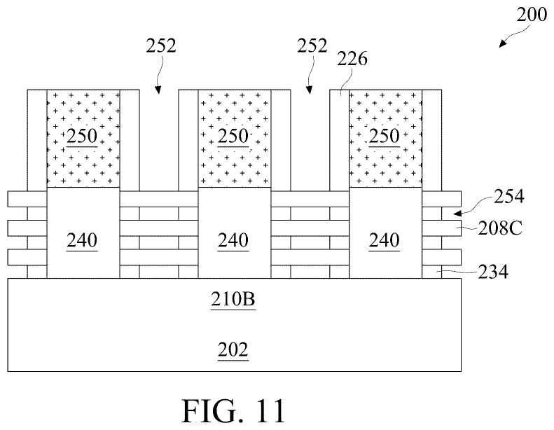

In some embodiments, the sacrificial semiconductor layers 206 may be removed in a later process, thereby leaving the channel semiconductor layers 208, which define channel nanostructures (e.g., 208C of FIG. 11) for the GAA device 200. The thickness of sacrificial semiconductor layers 206 thus determines the spacing between adjacent channel nanostructures. In some embodiments, the thickness of the sacrificial semiconductor layers 206 may range from about 8 nm to about 15 nm. The thickness of the channel semiconductor layers 208 is chosen based on, for example, manufacturing considerations, transistor performance considerations, and the like. In some embodiments, the thickness of the channel semiconductor layers 208 may range from about 4 nm to about 10 nm.

The number of sacrificial semiconductor layers 206 and channel semiconductor layers 208 depends on the desired number of channel nanostructures in the GAA device 200. In some embodiments, the number of channel semiconductor layers 208 is from, for example, 2 to 10, to form a stack of 2 to 10 vertically separated channel nanostructures. In some embodiments and as illustrated in FIG. 2, the stack 204 includes four (4) layers of sacrificial semiconductor layers 206 and three (3) layers of channel semiconductor layers 208.

The sacrificial semiconductor layers 206 and channel semiconductor layers 208 are epitaxially grown layer-by-layer from a top surface of the substrate 202. In some embodiments, the sacrificial semiconductor layers 206 and channel semiconductor layers 208 are grown by a molecular beam epitaxy (MBE) process, a chemical vapor deposition (CVD) process, such as a metal organic CVD (MOCVD) process, or other suitable epitaxy growth processes.

The epitaxy growth results in the sacrificial semiconductor layers 206 and the channel semiconductor layers 208 having the same crystal orientation as the substrate 202.

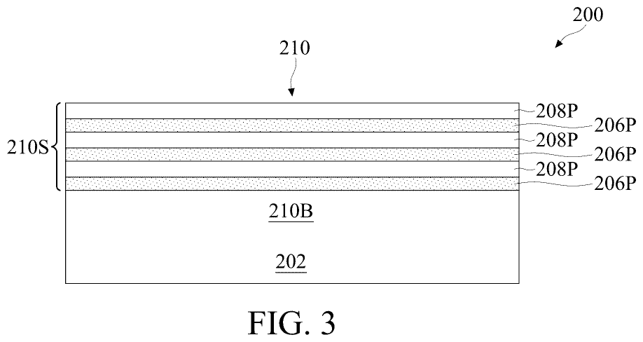

Referring to FIGS. 1 and 3, the method 100 proceeds to operation 104, where at least one fin structure 210 is formed from the stack 204, in accordance with some embodiments. FIG. 3 is a cross-sectional view of the GAA device 200 after forming the at least one fin structure 210.

In some embodiments, the stack 204 and a portion of the substrate 202 are patterned to form at least one fin structure 210. Each fin structure 210 extends vertically along the Z-direction from the substrate 202 and has a length dimension along the X direction and a width dimension along the Y direction. The width of each fin structure 210 may range from about 10 nm to about 90 nm. Each fin structure 210 includes a base portion 210B and a fin stack portion 210S. The base portion 210B is formed from the substrate 202, while the fin stack portion 210S is formed from the stack 204 and includes portions of the sacrificial semiconductor layers 206 (herein referred to as sacrificial semiconductor portions 206P) and portions of the channel semiconductor layers 208 (herein referred to as channel semiconductor portions 208P).

In some embodiments, the at least one fin structure 210 may be formed using photolithography and etch processes. During a photolithography process, a hard mask layer (not shown) may be first formed over the topmost surface of the stack 204. In some embodiments, the hard mask layer includes a dielectric material such as, for example, silicon nitride (SiN), silicon carbon nitride (SiCN), silicon oxycarbide (SiOC), silicon oxycarbon nitride (SiOCN), or a combination thereof. In some embodiments, the hard mask layer is formed by CVD, plasma-enhanced CVD (PECVD), physical vapor deposition (PVD), atomic layer deposition (ALD), or other suitable deposition processes. In some embodiments, the hard mask layer may have a double-layer structure including a pad oxide layer and a pad nitride layer formed over the pad oxide layer. In some embodiments, the pad oxide layer includes silicon oxide, which can be formed by thermal oxidation. The pad nitride layer includes SiN, which can be formed by CVD, PECVD, PVD, ALD, or other suitable deposition processes.

Subsequently, a photoresist layer is applied to the hard mask layer by, for example, spin coating. Then, the photoresist layer is exposed according to a mask of patterns, and is developed to form the patterns in the photoresist layer. The photoresist layer with the patterns can be used as an etch mask to pattern other layers. In some embodiments, patterning the photoresist layer is performed using an extreme ultraviolet (EUV) light lithography process. The patterned photoresist layer is then used to protect regions of the substrate 202 and the sacrificial semiconductor layers 206 and channel semiconductor layers 208 formed thereupon, while an etching process forms the fin structure 210. In some embodiments, the etching process may be a dry etching process, such as plasma etching or reactive ion etching (RIE), a wet etching process, or a combination thereof.

In various other embodiments, the fin structure 210 may be formed using suitable processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process.

Mandrels are formed alongside the patterned sacrificial layer using a self-aligned process. The sacrificial layer is then removed, and the remaining mandrels are used as an etch mask to pattern the stack 204 and the substrate 202 to provide the fin structures 210.

Subsequently, an isolation feature (not shown) may be formed over the substrate 202 and on opposite sides of the fin structures 210. In some embodiments, the isolation feature may include silicon oxide, silicon nitride, silicon oxynitride, silicon carbonitride, silicon oxycarbonitride fluorine-doped silicate glass (FSG), a low-k dielectric, and/or other suitable directed materials. In an example process, the isolation feature may be formed by first depositing a dielectric layer over the substrate 202, filling the trenches between the fin structures 210. In various examples, the dielectric layer may be deposited by a CVD process, a subatmospheric CVD (SACVD) process, a flowable CVD process, an atomic layer deposition (ALD) process, a physical vapor deposition (PVD) process, spin-on coating, and/or other suitable processes. The deposited dielectric material is then planarized, for example, by a chemical mechanical polishing (CMP) process. The planarized dielectric layer is further recessed using a suitable anisotropic etching process to expose the fin stack portions 210S of the at least one fin structure 210. In some embodiments, the anisotropic etching process is a dry etching process, a wet etching process, or a combination thereof. In some embodiments, a top surface of the isolation feature is substantially planar or lower than the bottom surfaces of the bottommost sacrificial semiconductor portions 206P, so that the fin stack portion 210S rises above the isolation feature.

Next, the hard mask layer, if not removed during the formation of the isolation feature, is removed from the topmost surfaces of the fin structure 210. The removal of the hard mask layer may be performed using an anisotropic etching process. The etching process may be a dry etching process, such as RIE, a wet etching process, or a combination thereof.

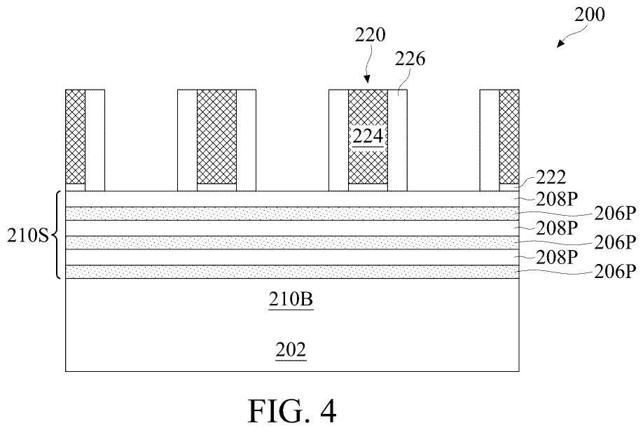

Referring to FIGS. 1 and 4, the method 100 proceeds to operation 106, where sacrificial gate structures 220 are formed over the at least one fin structure 210, in accordance with some embodiments. FIG. 4 is a cross-sectional view of the GAA device 200 after forming the sacrificial gate structures 220. The sacrificial gate structures 220 are formed across the fin structure 210, along the sidewalls and the topmost surface of the fin structure 210.

The sacrificial gate structure 220 includes a sacrificial gate stack (222, 224) and gate spacers 226. In embodiments of the present disclosure, the sacrificial gate stack (222, 224) will be replaced with a metal gate stack.

In some embodiments, the sacrificial gate stack (222, 224) includes a sacrificial gate dielectric 222 and a sacrificial gate electrode 224 on the sacrificial gate dielectric 222. In some embodiments, the sacrificial gate stack (222, 224) may further include a sacrificial gate cap (not shown) on top of the sacrificial gate electrode 224.

In some embodiments, the sacrificial gate dielectric 222 may be made of silicon oxide, silicon nitride, or silicon oxynitride. The sacrificial gate electrode 224 may be made of silicon, such as polycrystalline silicon or amorphous silicon. In some embodiments, the sacrificial gate stack (222, 224) may be formed by first conformally depositing a sacrificial gate dielectric layer over the fin structure 210 and the isolation feature. A sacrificial gate electrode layer is then blanketly deposited on the sacrificial gate dielectric layer such that the fin structure 210 is fully embedded in the sacrificial gate electrode layer. The thickness of the sacrificial gate dielectric layer may range from about 1 nm to about 5 nm in some embodiments. The thickness of the sacrificial gate electrode layer may range from about 100 nm to about 200 nm in some embodiments. In some embodiments, the sacrificial gate electrode layer is subjected to a planarization operation, for example, CMP. The sacrificial gate dielectric layer and the sacrificial gate electrode layer may be deposited using CVD, PECVD, PVD, ALD, or other suitable deposition processes. Subsequently, the sacrificial gate dielectric layer and the sacrificial gate electrode layer are patterned using photolithography and etching processes. For example, a photoresist layer (not shown) is applied over the sacrificial gate electrode layer and lithographically patterned by lithographic exposure and development. The pattern in the photoresist layer is sequentially transferred into the sacrificial gate electrode layer and the sacrificial gate dielectric layer by at least one anisotropic etching process, thereby forming the sacrificial gate stack (222, 224), which comprises the remaining portions of the sacrificial gate dielectric layer and the sacrificial gate electrode layer. The anisotropic etching process may be a dry etching process, for example, RIE, a wet etching process, or a combination thereof. If not completely consumed, the remaining photoresist layer after formation of the sacrificial gate stack (222, 224) is removed by, for example, ashing.

The gate spacers 226 are disposed on sidewalls of the sacrificial gate stack (222, 224). In some embodiments, the gate spacers 226 may include a dielectric material such as, for example, an oxide, a nitride, an oxynitride, or combinations thereof. In some embodiments, the gate spacers 226 are made of silicon nitride. In some embodiments, the gate spacers 226 may be formed by first depositing a conformal gate spacer material layer on exposed surfaces of the sacrificial gate stack (222, 224), the fin structure 210, and the isolation feature and then etching the gate spacer material layer to remove horizontal portions of the gate spacer material layer. In some embodiments, the gate spacer material layer may be deposited, for example, by CVD, PECVD, or ALD. In some embodiments, the gate spacer material layer may be etched by dry etch, such as, for example, plasma etching or RIE. Vertical portions of the gate spacer material layer present on the sidewalls of the sacrificial gate stack (222, 224) constitute the gate spacers 226.

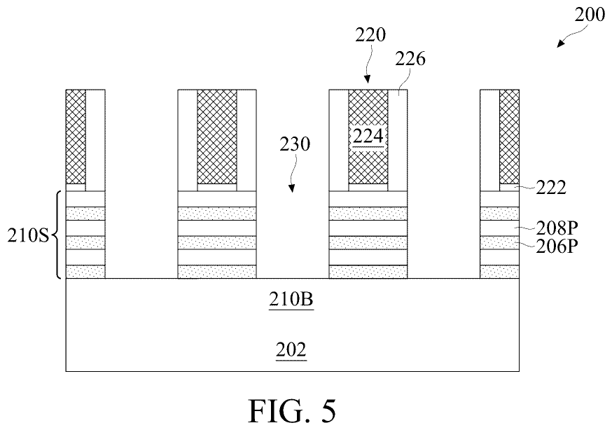

Referring to FIGS. 1 and 5, the method 100 proceeds to operation 108, where source/drain trenches 230 are formed in the at least one fin structure 210, in accordance with some embodiments. FIG. 5 is a cross-sectional view of the GAA device 200 after forming the source/drain trenches 230.

The source/drain trenches 230 may extend through the fin stack portion 210S. In some embodiments, the sacrificial semiconductor portions 206P and the channel semiconductor portions 208P in the source/drain regions, or regions not covered by the sacrificial gate structures 220, are etched using the sacrificial gate structures 220 as an etch mask to form the source/drain trenches 230. The etching may be performed by a dry etching process, such as plasma etching or RIE. An exemplary dry etching process may implement an oxygen-containing gas, hydrogen, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. Alternatively, the etching may be performed by a wet etching process that uses an etchant such as a mixture of ammonium hydroxide, hydrogen peroxide, and water (APM), tetramethylammonium hydroxide (TMAH), or ammonium hydroxide (NH₄OH). As shown in FIG. 5, the sidewalls of the sacrificial semiconductor portions 206P and the channel semiconductor portions 208P are exposed in the source/drain trenches 230. In some embodiments, the base portions 210B may also be partially etched, so that the source/drain trenches 230 extend into the base portion 210B. Accordingly, the bottom surfaces of the source/drain trenches 230 may be coplanar with or lower than the top surface of the base portion 210B.

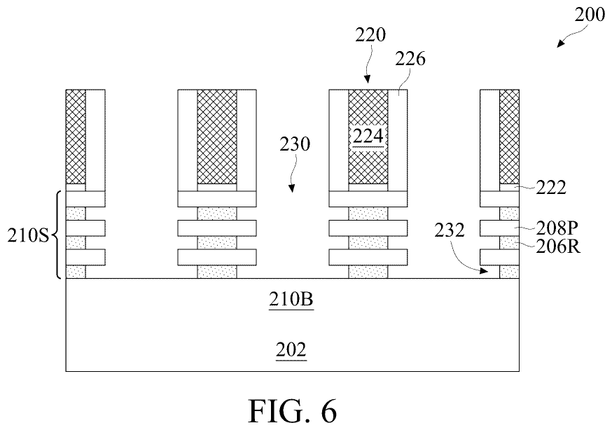

Referring to FIGS. 1 and 6, the method 100 proceeds to operation 110, where the sacrificial semiconductor portions 206P are recessed to form lateral openings 232, in accordance with some embodiments. FIG. 6 is a cross-sectional view of the GAA device 200 after recessing the sacrificial semiconductor portions 206P to form the lateral openings 232.

The end portions of the sacrificial semiconductor portions 206P exposed in the source/drain trenches 230 are selectively and laterally recessed to form the lateral openings 232 between the channel semiconductor portions 208P, while the exposed channel semiconductor portions 208P are substantially unetched.

In some embodiments, a wet etching process may be performed to selectively remove the portions of the sacrificial semiconductor portions 206P that underlie the gate spacers 226. In some embodiments, the amount of the sacrificial semiconductor portions 206P etched is controlled so that the lateral etching distance is no greater than the width of the gate spacers 226. Depending on the materials forming the sacrificial and channel semiconductor portions 206P, 208P, the wet etching process may use an etchant such as, but not limited to, ammonium hydroxide (NH₄OH), tetramethylammonium hydroxide (TMAH), ethylenediamine pyrocatechol (EDP), and potassium hydroxide (KOH) solutions. Alternatively, operation 110 may first selectively oxidize lateral ends of the sacrificial semiconductor portions 206P that are exposed in the source/drain trenches 230 to increase the etching selectivity between the sacrificial semiconductor portions 206P and the channel semiconductor portions 208P. In some embodiments, the oxidation process may be performed by exposing the GAA device 200 to a wet oxidation process, a dry oxidation process, or a combination thereof. The remaining portions of the sacrificial semiconductor portions 206P are herein referred to as recessed sacrificial semiconductor portions 206R.

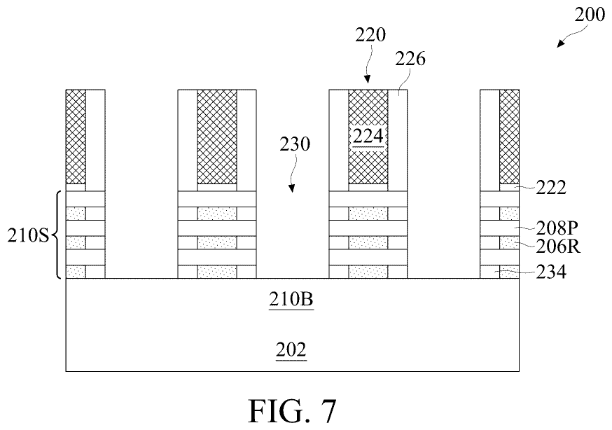

Referring to FIGS. 1 and 7, the method 100 proceeds to operation 112, wherein inner spacers 234 are formed in the lateral openings 232, in accordance with some embodiments. FIG. 7 is a cross-sectional view of the GAA device 200 after forming the inner spacers 234.

To form the inner spacers 234, an inner spacer material layer is deposited over the various components of GAA device 200 and in the lateral openings 232. In some embodiments, the inner spacer material layer may include a dielectric nitride, for example, silicon nitride, silicon oxycarbonitride, silicon carbonitride, or any suitable dielectric material. In some embodiments, the inner spacer material layer may be formed by CVD, ALD, or any other suitable conformal deposition processes. In some embodiments, the inner spacer material layer may be formed to have a thickness such that the lateral openings 232 are completely filled by the inner spacer material layer so that the resulting inner spacers 234 contact the sidewalls of the recessed sacrificial semiconductor portions 206R.

An etching process, such as an anisotropic etching process, is then performed to remove portions of the inner spacer material layer disposed outside the lateral openings 232. The remaining portions of the inner spacer material layer (i.e., portions disposed inside the inner spacer recesses) form the inner spacers 234. In some embodiments, the anisotropic etching process may be a wet etching process that includes the use of an etchant such as, for example, buffered hydrofluoric acid (BHF), hydrofluoric acid (HF), hydrofluoric nitric acid (HNA), phosphoric acid, HF diluted by ethylene glycol (HFEG), hydrochloric acid (HCl), or any combination thereof. In some embodiments, the anisotropic etching process may be a dry etching process that includes the use of an oxygen-containing gas, hydrogen, nitrogen, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas (e.g., CF₃I), other suitable gases and/or plasmas, and/or combinations thereof.

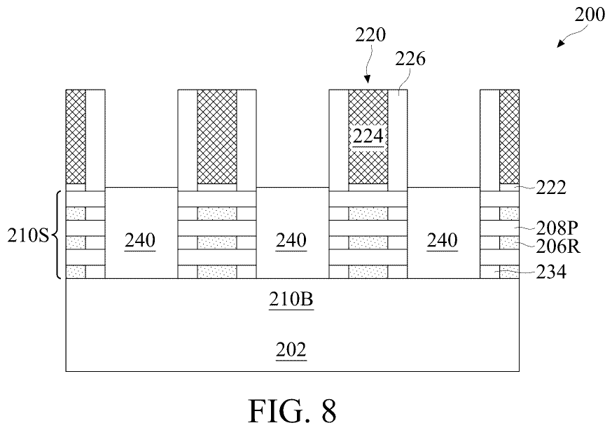

Referring to FIGS. 1 and 8, the method 100 proceeds to operation 114, where source/drain features 240 are formed in the source/drain trenches 230, in accordance with some embodiments. FIG. 8 is a cross-sectional view of the GAA device 200 after forming the source/drain features 240.

The source/drain features 240 are disposed on opposite sides of the sacrificial gate structures 220, the channel semiconductor portions 208P, and the recessed sacrificial semiconductor portions 206R such that the source/drain features 240 are in contact with the channel semiconductor portions 208P but are separated from the recessed sacrificial semiconductor portions 206R by the inner spacers 234.

The source/drain features 240 are epitaxially grown in the source/drain trenches 230. The epitaxy process may include CVD deposition (for example, vapor-phase epitaxy (VPE) ultra-high vacuum CVD (UHV-CVD), low pressure CVD (LPCVD), plasma-enhanced CVD (PECVD)), molecular beam epitaxy (MBE), other suitable selective epitaxy growth (SEG) processes, or combinations thereof. During the epitaxy process, the source/drain features 240 grow from the exposed semiconductor surfaces, including sidewall surfaces of the channel semiconductor portions 208P and sidewall surfaces of the base portion 210B.

The source/drain features 240 may include any suitable material for n-type or p-type FET devices. For example, when n-type FET devices are formed. the source/drain features 240 may include materials exerting a tensile strain in the channel regions, such as Si, SiC, or the like, and may be in-situ doped during the epitaxy process by introducing an n-type dopant, such as phosphorus (P), arsenic (As), or ex-situ doped using an implantation process (i.e., a junction implant process). The concentration of the n-type dopant may range from 5×10¹⁹ to 5×10²¹ /cm³. Likewise, when p-type FET devices are formed, the source/drain features 240 may include materials exerting a compressive strain in the channel regions, such as Si, SiGe, or the like and may be in-situ doped during the epitaxy process by introducing a p-type dopant, such as boron (B), aluminum (Al), gallium (Ga), and indium (In), or ex-situ doped using an implantation process (i.e., a junction implant process). The concentration of the p-type dopant may range from 5×10¹⁹ to 5×10²¹/cm³. The source/drain features 240 may have surfaces raised from respective surfaces of the channel semiconductor portions 208P and may have facets. In some embodiments, the source/drain features 240 are p-type source/drain features and include boron-doped SiGe or SiGe with a germanium (Ge) concentration in the range from 10 to 50%. In some embodiments, the source/drain features 240 are n-type source/drain features and include phosphorus- or arsenic-doped Si.

In some embodiments, an annealing process, for example, rapid thermal annealing (RTA) or laser annealing, may be performed to activate dopants in the source/drain features 240.

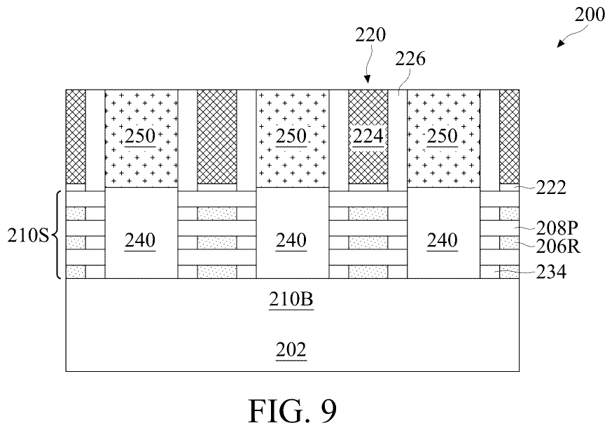

Referring to FIGS. 1 and 9, the method 100 proceeds to operation 116, where an interlayer dielectric (ILD) layer 250 is formed over the source/drain features 240, in accordance with some embodiments. FIG. 9 is a cross-sectional view of the GAA device 200 after forming the ILD layer 250.

In some embodiments, the ILD layer 250 may include a low-k dielectric material having a dielectric constant lower than the dielectric constant (about 3.9) of silicon dioxide. The low-k dielectric material may include tetraethylorthosilicate (TEOS) formed oxide (e.g., reacting TEOS with oxygen using CVD to deposit silicon oxide), un-doped silicate glass, or doped silicon oxide such as borophosphosilicate glass (BPSG), fluoride-doped silica glass (FSG), phosphosilicate glass (PSG), boron doped silicon glass (BSG), other suitable low-k dielectric material, or combinations thereof. The ILD layer 250 may include a multi-layer structure having multiple dielectric materials and may be formed by CVD, flowable CVD (FCVD), spin coating, or other suitable deposition processes. In some embodiments, forming the ILD layer 250 further includes performing a CMP process to planarize a top surface of the ILD layer 250, such that the topmost surfaces of the sacrificial gate structures 220 are exposed. In some embodiments, the top surface of the ILD layer 250 is coplanar with the top surfaces of the gate spacers 226.

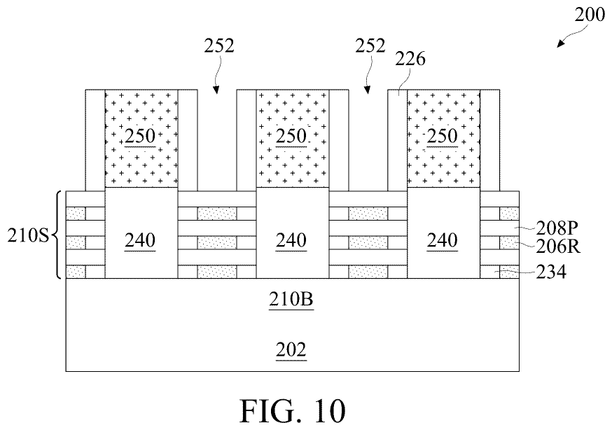

Referring to FIGS. 1 and 10, the method 100 proceeds to operation 118, where the sacrificial gate stacks (222, 224) are removed, in accordance with some embodiments. FIG. 10 is a cross-sectional view of the GAA device 200 after removing the sacrificial gate stacks (222, 224).

One or more etching processes are performed to selectively remove various components of each of the sacrificial gate stacks (222, 224), including the sacrificial gate dielectric 222 and the sacrificial gate electrode 224. The removal of the sacrificial gate stacks (222, 224) forms gate trenches 252 that expose the channel semiconductor portions 208P and the recessed sacrificial semiconductor portions 206R in the channel regions of the fin structure 210. The ILD layer 250 protects the source/drain features 240 during the etching process. The etching process may be a dry etching process, a wet etching process, or a combination thereof. The etching process can be tuned such that the sacrificial gate dielectric 222 and the sacrificial gate electrode 224 are removed without (or minimally) etching other elements in the GAA device 200, including the ILD layer 250 and the gate spacers 226. For example, in instances where the sacrificial gate electrode 224 is composed of polysilicon and the ILD layer 250 is composed of silicon oxide, a wet etchant such as a TMAH solution may be used to selectively remove the sacrificial gate electrode 224. The sacrificial gate dielectric 222 is thereafter removed using plasma dry etching and/or wet etching.

Referring to FIGS. 1 and 11, the method 100 proceeds to operation 120, where the recessed sacrificial semiconductor portions 206R are removed, in accordance with some embodiments. FIG. 11 is a cross-sectional view of the GAA device 200 after removing the recessed sacrificial semiconductor portions 206R.

The selective removal of the recessed sacrificial semiconductor portions 206R releases the channel semiconductor portions 208P, thereby forming channel nanostructures 208C. The channel nanostructures 208C may be nanowires or nanosheets.

In some embodiments, the recessed sacrificial semiconductor portions 206R may be removed by a selective etching process using an etchant that is selective to the sacrificial semiconductor material, such that the recessed sacrificial semiconductor portions 206R are removed without substantially attacking the channel semiconductor portions 208P. In some embodiments, the etching process is an isotropic etching process which can be a dry etching process or a wet etching process. In some embodiments, the selective etching process may include oxidizing the recessed sacrificial semiconductor portions 206R using a suitable oxidizer, such as ozone. Thereafter, the oxidized recessed sacrificial semiconductor portions 206R may be selectively removed. In some embodiments, when the channel semiconductor portions 208P include Si and the recessed sacrificial semiconductor portions 206R include SiGe, the recessed sacrificial semiconductor portions 206R may be selectively removed by applying an HCl gas at a temperature of about 500° C. to about 700° C., or applying a gas mixture of CF₄, SF₆, and CHF₃. The inner spacers 234 serve as etch stop layers to protect the source/drain features 240 during removal of the recessed sacrificial semiconductor portions 206R in the gate trenches 252. As a result, the remaining channel semiconductor portions 208P form the channel nanostructures 208C.

After removal of the recessed sacrificial semiconductor portions 206R, a trimming operation may be performed to reduce the thickness of the channel nanostructures 208C, thereby improving the gate fill window. The trimming operation can utilize any suitable etching process, such as dry etching, wet etching, or a combination thereof. In some embodiments, the channel nanostructures 208C may have a thickness ranging from 3 nm to 8 nm.

As shown in FIG. 11, gaps 254 (e.g., empty spaces) are formed between adjacent channel nanostructures 208C and between the bottommost channel nanostructure 208C and the base portion 210B, as a result of the removal of the recessed sacrificial semiconductor portions 206R and nanosheet trimming. The gaps 254 define the spacing between adjacent channel nanostructures 208C. In some embodiments, the spacing between the adjacent channel nanostructures 208C (also referred to as sheet-to-sheet spacing) may range from about 8 nm to about 15 nm.

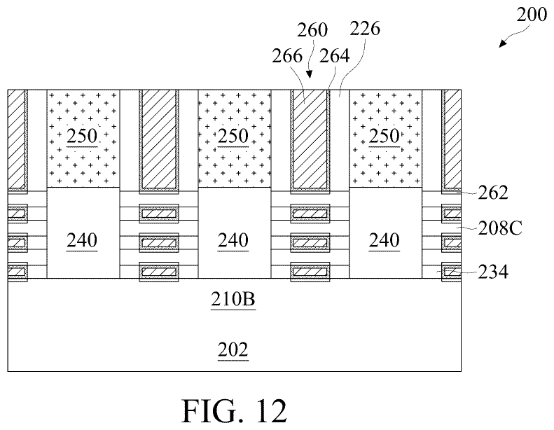

Referring to FIGS. 1 and 12, the method 100 proceeds to operation 122, where gate stacks (262, 264, 266) are formed in the gate trenches 252 and the gaps 254, in accordance with some embodiments. FIG. 12 is a cross-sectional view of the GAA device 200 after forming the gate stacks (262, 264, 266).

Each gate stack (262, 264, 266) is disposed over and between the vertically spaced channel nanostructures 208C, respectively, and over the base portion 210B. In some embodiments, the gate stack (262, 264, 266) includes an interfacial layer 262, a gate dielectric 264, and a gate electrode 266.

The gate stacks (262, 264, 266) are formed by first forming interfacial layers 262 on the exposed surfaces of the channel nanostructures 208C and the base portion 210B. The interfacial layer promotes adhesion of the gate dielectric 264 to the channel nanostructures 208C. In some embodiments, the interfacial layer 262 may include a dielectric material such as silicon oxide. In some embodiments, the interfacial layer 262 may be formed by chemical oxidation or thermal oxidation of surface portions of the channel nanostructures 208C and the base portion 210B. For example, in some embodiments, the interfacial layer 262 is formed using an ozonated deionized water comprising ozone. The thickness of the interfacial layer 262 ranges from about 0.5 nm to about 1.5 nm. In some embodiments, the interfacial layer 262 is about 1 nm thick, achieved by oxidizing around 1 nm of the channel nanostructures 208C.

Afterwards, a gate dielectric layer is conformally deposited over the interfacial layers 262. The gate dielectric layer wraps around the channel nanostructures 208C, and is on the bottom and sidewalls of the gate trench 252. In some embodiments, the gate dielectric layer may include a high-k dielectric material having a dielectric constant greater than silicon dioxide. Examples of high-k dielectric materials include, but are not limited to, hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), zirconium oxide (ZrO₂), aluminum oxide (Al₂O₃), titanium oxide (TiO₂), and hafnium oxide-alumina (HfO₂-Al₂O₃) alloy. The gate dielectric 264 may be formed by CVD, ALD or other suitable conformal deposition methods. In some embodiments, the gate dielectric layer is formed using a conformal deposition process, such as ALD, in order to ensure that the gate dielectric layer has a uniform thickness around each of the channel nanostructures 208C. The gate dielectric layer may be formed to have a thickness ranging from about 1 nm to about 2.5 nm. In some embodiments, the gate dielectric layer may be formed to have a thickness of about 1.5 nm.

Next, a gate electrode layer is formed on the gate dielectric layer to fill the gate trench 252 and the gaps 254. For an n-type FET, the gate electrode layer may include an n-type work function material adapted to tune the threshold voltage for the n-type FET. Suitable n-type work function materials include, but are not limited to, titanium aluminum (TiAl), titanium aluminum carbide (TiAlC), titanium carbide (TiC), tantalum silicon nitride (TaSiN), tantalum aluminum carbide (TaAlC), tantalum aluminum nitride (TaAlN), and combinations thereof. For a p-type FET, the gate electrode layer may include a p-type work function material adapted to tune the threshold voltage for p-type FET. Suitable p-type work function materials include, but are not limited to, titanium nitride (TiN), titanium silicon nitride (TiSiN), tantalum nitride (TaN), tungsten (W), tungsten carbon nitride (WCN), molybdenum nitride (MoN), titanium tungsten nitride (TiWN), and combinations thereof. The gate electrode layer may be formed by any suitable deposition process, such as CVD, PECVD, PVD, or electrochemical plating.

Next, excess portions of the gate dielectric layer and the gate electrode layer that are deposited on the top surface of the ILD layer 250 and the gate spacers 226 are removed in a planarization process, such as a CMP process, to form the gate stacks (262, 264, 266). The remaining portion of the gate dielectric layer in each gate trench 252 and the corresponding underlying gaps 254 constitutes the gate dielectric 264, and the remaining portion of the gate electrode layer in each gate trench 252 and the corresponding underlying gaps 254 constitutes the gate electrode 266. The top surface of the gate stack (262, 264, 266) may be coplanar with the top surfaces of the ILD layer 250 and the gate spacers 226. In some embodiments, the gate stack (262, 264, 266) may have a height ranging from 5 nm to 40 nm and a lateral dimension (i.e., width) ranging from 5 nm to 30 nm.

The gate stack (262, 264, 266) thus formed surrounds the channel nanostructures 208C and fills the gaps 254 between the channel nanostructures 208C and the gap 254 between the bottommost channel nanostructure 208C and the base portion 210B. Between the channel nanostructures 208C, the gate electrode 266 is circumferentially surrounded (in the cross-sectional view) by the gate dielectric 264. In the portion of the gate stack (262, 264, 266) formed over the topmost channel nanostructure 208C, the gate electrode 266 is formed over the gate dielectric 264, with the gate dielectric 264 wrapping around the gate electrode 266. Each gate stack (262, 264, 266) and corresponding gate spacers 226 on the sidewalls of the gate stack (262, 264, 266) constitute a gate structure 260.

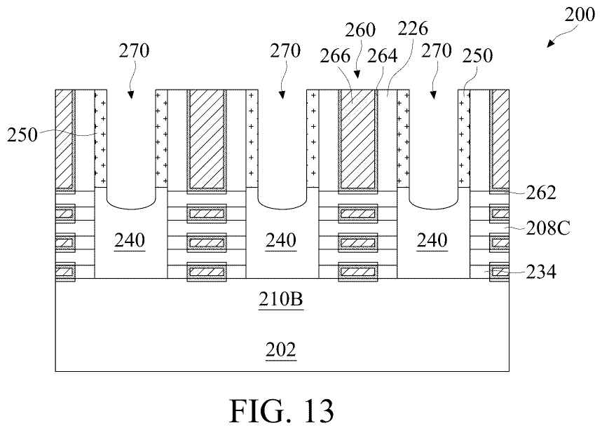

Referring to FIGS. 1 and 13, the method 100 proceeds to operation 124, where source/drain contact openings 270 are formed to expose the source/drain features 240, in accordance with some embodiments. FIG. 13 is a cross-sectional view of the GAA device 200 after forming the source/drain contact openings 270 to expose the source/drain features 240.

The source/drain contact openings 270 extend through the ILD layer 250 to expose portions of the source/drain features 240. In some embodiments, the source/drain contact openings 270 are formed by removing corresponding portions of the ILD layer 250 using an etching process. For example, the formation of the source/drain contact openings 270 includes applying a photoresist layer (not shown) over the ILD layer 250 and the gate structures 260 by a suitable deposition process, such as spin-on coating, pattering the photoresist layer to form a patterned photoresist layer by a lithography method, and etching the ILD layer 250 to remove portions of the ILD layer 250 that are exposed by the patterned photoresist layer. In some embodiments, the ILD layer 250 is etched using a dry etching process, such as, for example, RIE or plasma etch. In some embodiments, the ILD layer 250 is etched using a wet etching process. The gate spacers 226 are protected by the patterned photoresist layer and remain intact during the ILD layer 250 etching.

After formation of the source/drain contact openings 270 through the ILD layer 250, the patterned photoresist layer is removed, for example, by ashing. Alternatively, in some embodiments, a hard mask is used such that the source/drain contact opening pattern is transferred from the patterned photoresist layer to the hard mask by a first etch and then transferred to the ILD layer 250 by a second etch.

In some embodiments and as shown in FIG. 13, the etch may also remove a portion of each source/drain feature 240, a bottom surface of each source/drain contact opening 270 is thus below the top surface of a corresponding source/drain feature 240. In some embodiments, each source/drain contact opening 270 has rounded bottom corners.

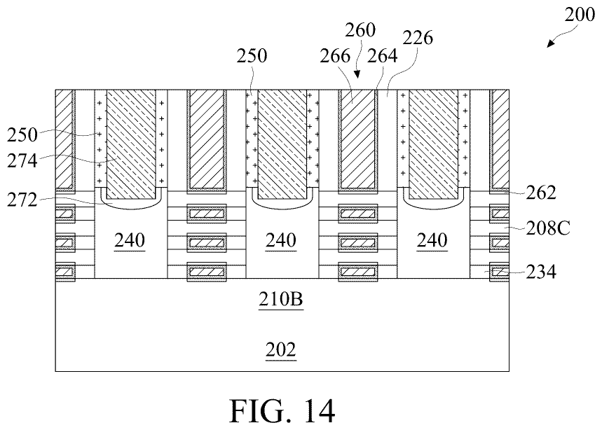

Referring to FIGS. 1 and 14, the method 100 proceeds to operation 126, where silicide features 272 and source/drain contact features 274 are sequentially formed in the source/drain contact openings 270, in accordance with some embodiments. FIG. 14 is a cross-sectional view of the GAA device 200 after sequentially forming the silicide features 272 and the source/drain contact features 274 in the source/drain contact openings 270.

The silicide features 272 and source/drain contact features 274 are formed such that an electrical conductivity of the silicide features 272 is between an electrical conductivity of the source/drain features 240 and an electrical conductivity of the source/drain contact features 274, with the electrical conductivity of the source/drain contact features 274 being the highest.

In some embodiments, the silicide features 272 are first formed in contact with the source/drain features 240. To form silicide features 272, one or more metals may be deposited over portions of the source/drain features 240 exposed by the source/drain contact openings 270. Then the GAA device 200 is annealed to allow the one or more metals and the semiconductor material of the source/drain features 240 to react. Thereafter, the unreacted portion of the one or more metals is removed, leaving the silicide features 272 over the source/drain features 240. The one or more metals may include chromium (Cr), titanium (Ti), tantalum (Ta), molybdenum (Mo), zirconium (Zr), hafnium (Hf), scandium (Sc), yttrium (Y), holmium, terbium (Tb), gadolinium (Gd), lutetium (Lu), dysprosium (Dy), erbium (Er), ytterbium (Yb), other noble metals, other refractory metals, rare earth metals, or their alloys, and may be deposited using CVD, PVD, ALD, or other suitable methods. The resulting silicide features 272 may include TiSi, CrSi, TaSi, MoSi, ZrSi, HfSi, ScSi, YSi, HoSi, TbSi, GdSi, LuSi, DySi, ErSi, or YbSi. In some embodiments, the silicide features 272 have a curved profile.

After forming the silicide features 272, the operation 126 deposits a metal layer (not shown) into the source/drain contact openings 270 and over the top surfaces of the ILD layer 250 and gate structures 260. The metal layer fully fills the source/drain contact openings 270 and is in direct contact with the silicide features 272. In some embodiments, the metal layer may include tungsten (W), cobalt (Co), molybdenum (Mo), ruthenium (Ru), copper (Cu), nickel (Ni), titanium (Ti), tantalum (Ta), aluminum (Al), titanium nitride (TiN), tantalum nitride (TaN), or other metals, and may be formed by CVD, PVD, ALD, plating, or other suitable processes. In some embodiments, the metal layer includes W, Mo, Ru, alloys thereof, the like, or combinations thereof. Subsequently, a planarization process, for example, CMP, is performed to remove excessive materials of the metal layer above the top surfaces of the ILD layer 250 and gate structures 260, thereby forming the source/drain contact features 274. In some embodiments, the source/drain contact features 274 have a height ranging from 5 nm to 40 nm, and a lateral dimension (i.e., width) ranging from 5 nm to 30 nm.

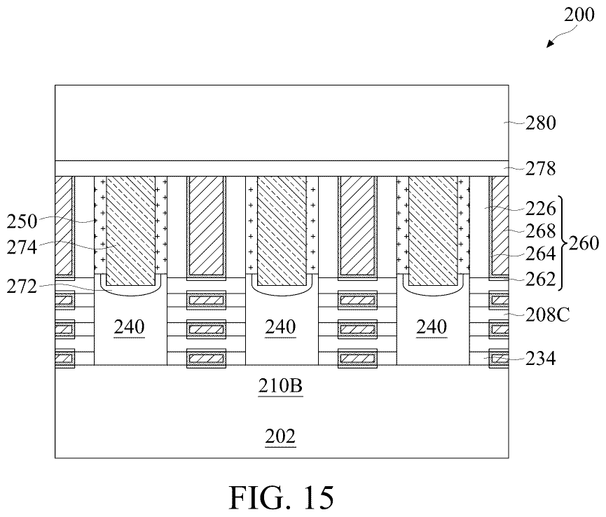

Referring to FIGS. 1 and 15, the method 100 proceeds to operation 128, where a contact etch stop layer 278 is formed over the ILD layer 250, the gate structures 260, and the source/drain contact features 274, following by forming a contact level dielectric layer 280 over the contact etch stop layer 278, in accordance with some embodiments. FIG. 15 is a cross-sectional view of the GAA device 200 after forming the contact etch stop layer 278 and the contact level dielectric layer 280.

The contact etch stop layer 278 is disposed on the top surfaces of the ILD layer 250, the gate structures 260, and the source/drain contact features 274. In some embodiments, the contact etch stop layer 278 may include silicon nitride (SiN), silicon carbon nitride (SiCN), silicon oxycarbonitride, or silicon oxycarbide; and may be formed by CVD, PVD, ALD, or other suitable deposition methods. In some embodiments, the contact etch stop layer 278 may have a thickness ranging from 1 nm to 10 nm.

The contact level dielectric layer 280 may include a low-k material the same as, or different from, that of the ILD layer 250. In some embodiments, the contact level dielectric layer 280 may include tetraethylorthosilicate (TEOS) formed oxide (e.g., reacting TEOS with oxygen using CVD to deposit silicon oxide), undoped silicate glass, or doped silicon oxide such as borophosphosilicate glass (BPSG), fluoride-doped silica glass (FSG), phosphosilicate glass (PSG), boron-doped silicon glass (BSG), other suitable low-k dielectric materials, or combinations thereof. The contact level dielectric layer 280 may be formed by PECVD, FCVD, or other suitable deposition methods.

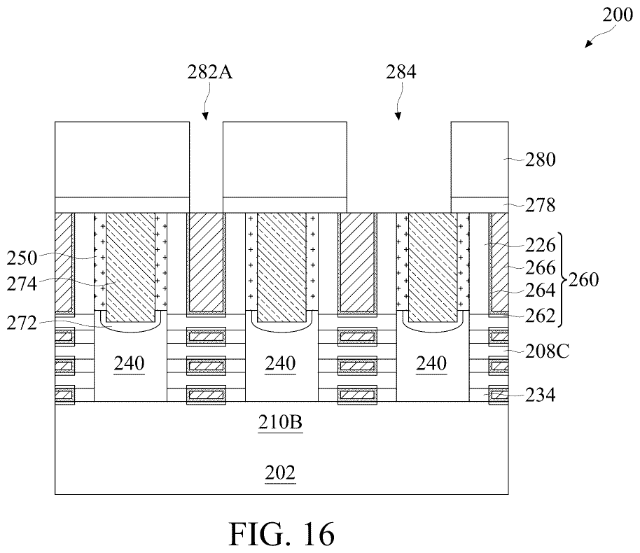

Referring to FIGS. 1 and 16, the method 100 proceeds to operation 129, where a gate via openings 282A and a trench 284 are formed through the contact level dielectric layer 280 and the contact etch stop layer 278, in accordance with some embodiments. FIG. 16 is a cross-sectional view of the GAA device 200 after forming the gate via opening 282A and the trench 284, in accordance with some embodiments.

The gate via opening 282A is disposed on a gate structure 260. The gate via opening 282A extends through the contact level dielectric layer 280 and the contact etch stop layer 278 to expose a portion of a gate electrode 266 in a corresponding one of the gate structures 260. The trench 284 extends through the contact level dielectric layer 280 and the contact etch stop layer 278 to expose a portion of a gate electrode in a corresponding one of the gate structures 260 and a source/drain contact feature 274 adjacent to one of the gate structures 260.

In some embodiments, the gate via openings 282A and the trench 284 may be formed by forming a patterned mask (not shown) on the contact level dielectric layer 280 to partially expose the contact level dielectric layer 280, etching the contact level dielectric layer 280 and the contact etch stop layer 278 through the patterned mask, and removing the patterned mask. The etching may be performed using dry etching, wet etching, or a combination thereof. The patterned mask may include a photoresist material or other suitable mask materials, and may be formed by coating a photoresist layer, soft-baking, exposing the photoresist layer through a photomask, post-exposure baking, and developing the photoresist layer, followed by hard-baking to thereby form the patterned mask.

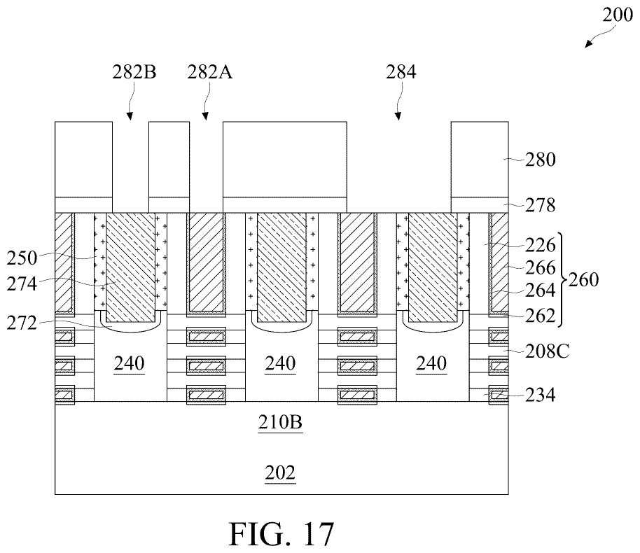

Referring to FIGS. 1 and 17, the method 100 proceeds to operation 130, where a source/drain contact via openings 282B is formed through the contact level dielectric layer 280 and the contact etch stop layer 278, in accordance with some embodiments. FIG. 17 is a cross-sectional view of the GAA device 200 after forming the source/drain contact via opening 282B, in accordance with some embodiments.

The source/drain contact via opening 282B is disposed on a source/drain contact feature 274. The source/drain contact via opening 282B extends through the contact level dielectric layer 280 and the contact etch stop layer 278 to expose a portion of a corresponding one of source/drain contact features 274.

In some embodiments, the source/drain contact via opening 282B may be formed by first forming a patterned mask (not shown) on the contact level dielectric layer 280 to cover the area where the gate via opening 282A and the trench 284 reside, while exposing the contact level dielectric layer 280 in the area overlying the corresponding source/drain contact feature 274. Subsequently, the contact level dielectric layer 280 and the contact etch stop layer 278 are etched through the patterned mask. After etching, the patterned mask is removed. The etching may be performed using dry etching, wet etching, or a combination thereof. The patterned mask may include a photoresist material or other suitable mask materials, and may be formed by coating a photoresist layer, soft-baking, exposing the photoresist layer through a photomask, post-exposure baking, and developing the photoresist layer, followed by hard-baking to thereby form the patterned mask.

Although in the illustrated embodiments of the present disclosure, the source/drain contact via openings 282B is formed in a separate fabrication step from the gate via opening 282A and the trench 284, in some embodiments, all three openings, i.e., the gate via opening 282A, the source/drain contact via opening 282B, and the trench 284 may be formed simultaneously using a single mask, thereby simplifying the fabrication process and improving alignment accuracy.

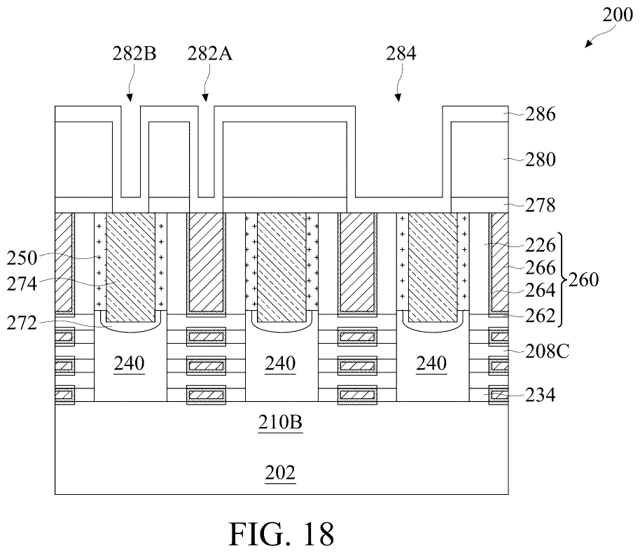

Referring to FIGS. 1 and 18, the method 100 proceeds to operation 132, where a conformal metal liner layer 286 is formed in the gate via openings 282A, the source/drain contact via opening 282B, and the trench 284 and over the top surface of the contact level dielectric layer 280, in accordance with some embodiments. FIG. 18 is a cross-sectional view of the GAA device 200 after forming the metal liner layer 286.

The metal liner layer 286 is formed along sidewall and bottom surfaces of the gate via openings 282A, the source/drain contact via opening 282B, and the trench 284. The metal liner layer 286 is disposed on the gate structure 260 and the source/drain contact features 274, and serves as a seed layer to facilitate the deposition of a contact metal for via contact and slot contact formation. Additionally, the metal liner layer 286 can function as a capping layer, protecting the metals in the underlying source/drain contact features 274 and gate electrodes 266 of the gate structures 260 from oxidation. In some embodiments, the metal liner layer 286 includes W, Mo, Ru, alloys thereof, the like, or combinations thereof. The metal liner layer 286 may be formed by a conformal deposition process such as CVD or ALD. The thickness of the metal liner layer 286 can vary relative to the contact etch stop layer 278; it may be thinner, equal to, or thicker than the contact etch stop layer 278. In some embodiments, the metal liner layer 286 has a thickness ranging from 0.5 nm to 5 nm. If the metal liner layer is too thin, it becomes difficult for the contact metal to form on it. Conversely, if the metal liner layer is too thick, it may merge within the via openings, making removal difficult.

In some embodiments, a pre-cleaning process may be performed to remove native oxide from the gate electrode 266 and the source/drain contact features 274. The removal may be achieved using a suitable surface cleaning process, such as a nitrogen plasma process. In some embodiments, the pre-cleaning process and the metal liner deposition process are performed in situ.

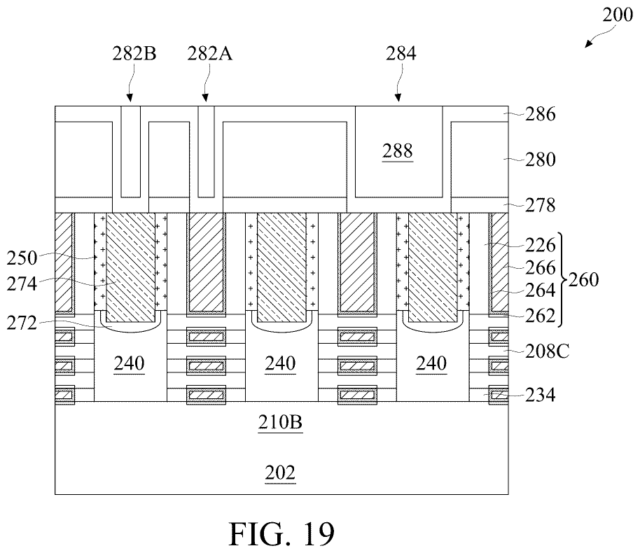

Referring to FIGS. 1 and 19, the method 100 proceeds to operation 134, where dielectric structures 288 are formed over the metal liner layer 286 and fill the gate via opening 282A, the source/drain contact via opening 282B, and the trench 284, in accordance with some embodiments. FIG. 19 is a cross-sectional view of the GAA device 200 after forming the dielectric structures 288.

The dielectric structures 288 protect the underlying portions of the metal liner layer 286 and may include material as a bottom antireflective coating. In some embodiments, the dielectric structures 288 may include a BARC polymer containing C, H, and O. Examples of BARC polymers may include, but are not limited to, polyhydroxy styrene (PHS), polymethacrylate, polyacrylate, poly(amic acid), and polyimide. In some embodiments, the dielectric structures 288 are formed by spin coating. Any excess BARC polymer outside the gate via opening 282A, source/drain contact via opening 282B, and trench 284 is removed so that the top surfaces of the dielectric structures 288 are coplanar with the topmost surface of the metal liner layer.

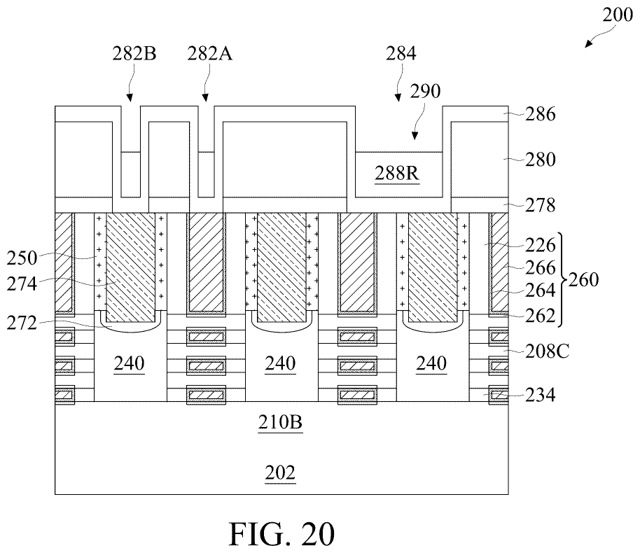

Referring to FIGS. 1 and 20, the method 100 proceeds to operation 136, where the dielectric structures 288 are recessed to form recesses 290 above recessed dielectric structures 288R, in accordance with some embodiments. FIG. 20 is a cross-sectional view of the GAA device 200 after recessing the dielectric structures 288.

In some embodiments, the dielectric structures 288 are recessed by an etch back process, which selectively etches the dielectric structures 288 without etching the metal liner layer 286. The etch back process removes the top portions of the dielectric structures 288, creating recesses 290 above dielectric structures 288. As a result of etching, the top surfaces of the dielectric structures 288 are positioned below the topmost surface of the metal liner layer 286, so that the upper sidewall portions of the metal liner layer 286 along the sidewalls of respective gate via opening 282A, source/drain contact via opening 282B, and trench 284 are exposed within the recesses 290. In some embodiments, the dielectric structures 288 may be etched using an etching gas comprising fluorine. The remaining portions of dielectric structures 288 in the lower portions of respective gate via opening 282A, source/drain contact via opening 282B, and trench 284 after recessing are herein referred to as recessed dielectric structures 288R.

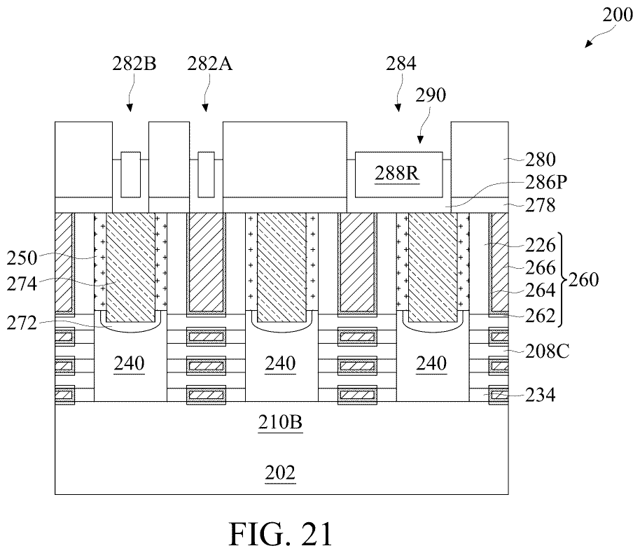

Referring to FIGS. 1 and 21, the method 100 proceeds to operation 138, where portions of the metal liner layer 286 over the contact level dielectric layer 280 and upper sidewalls of respective gate via opening 282A, source/drain contact via opening 282B, and trench 284 exposed by the recesses 290 are removed, in accordance with some embodiments.

FIG. 21 is a cross-sectional view of the GAA device 200 after removing the portions of the metal liner layer 286 over the contact level dielectric layer 280 and upper sidewalls of respective gate via opening 282A, source/drain contact via opening 282B, and trench 284 exposed by the recesses 290.

In some embodiments, the metal liner layer 286 is isotopically etched until the metal liner layer 286 is completely removed from the top surface of the contact level dielectric layer 280 and sidewall surfaces of the recesses 290. The etch my include a dry etching process using an etching gas comprising Cl and O or a wet etching process using a wet etchant containing S. In some embodiments, a SPM (sulfuric acid and hydrogen peroxide mixture) solution is used. Remaining portions of the metal liner layer 286 are herein referred to as metal liner portions 286P. The topmost surface of the metal liner portions 286P may be coplanar with or below the top surfaces of the recessed dielectric structures 288R.

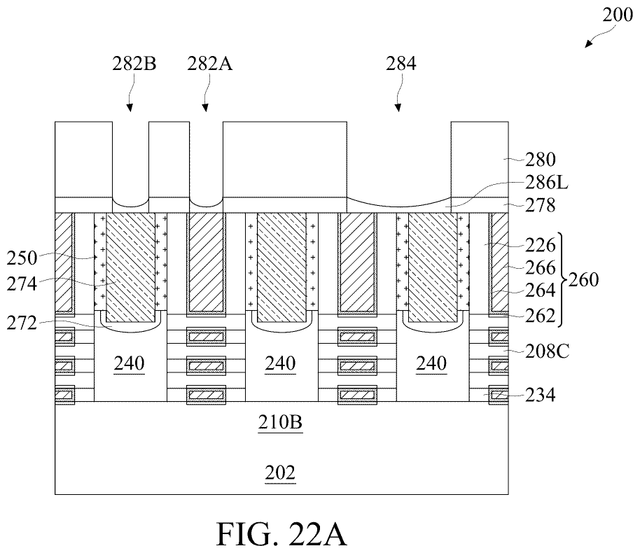

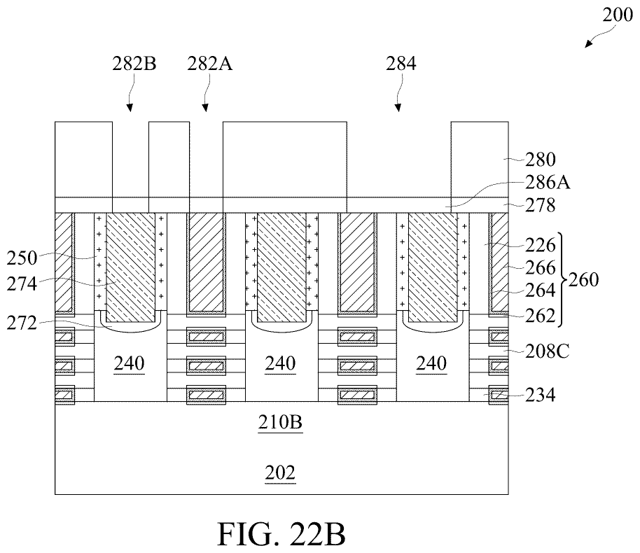

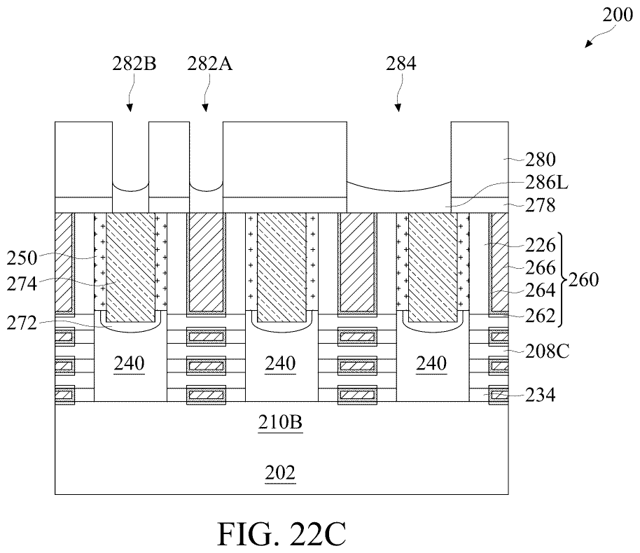

Referring to FIGS. 1 and 22A-22C, the method 100 proceeds to operation 140, where vertical portions of the metal liner portions 286P and the recessed dielectric structures 288R are removed, in accordance with some embodiments. FIGS. 22A-22C are cross-sectional views of the GAA device 200 after removing the vertical portions of the metal liner portions 286P and the recessed dielectric structures 288R.

A sidewall pull back process is performed to selectively remove the vertical portions of the metal liner portions 286P on sidewalls of the gate via opening 282A, source/drain contact via opening 282B, and trench 284 and the recessed dielectric structures 288R, without substantially etching the contact level dielectric layer 280 and the contact etch stop layer 278.

The sidewall pull back process is a timed etching process that continues until the recessed dielectric structures 288R are completely removed, exposing portions of the metal liner portions 286P on the bottom surfaces of the gate via opening 282A, source/drain contact via opening 282B, and trench 284. In some embodiments, the sidewall pull back process is an anisotropic etching process such as a reactive ion etching (RIE) process. In some embodiments, the etching process also recesses the top surfaces of the bottom portions of the metal liner portions 286P, such that the remaining metal liner portions 286P (herein referred to as metal liners 286L) have concave top surfaces. The top surfaces of the metal liners 286L may be lower than, coplanar with, or higher than the top surface of the contact etch stop layer, as shown in respective FIGS. 22A, 22B, and 22C.

In some embodiments, the vertical portions of the metal liner portions 286P and the recessed dielectric structures 288R may be removed through separate etching processes.

First, an etching process removes the vertical portions of the metal liner portions 286P. Then, a second etching process removes the recessed dielectric structures 288R, leaving the bottom portions of the metal liner portions 286P in the structure.

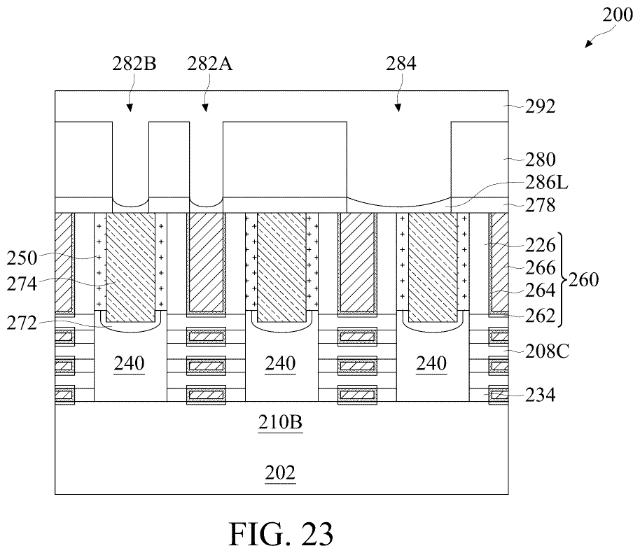

Referring to FIGS. 1 and 23, the method 100 proceeds to operation 142, where a conductive material layer 292 is deposited over the metal liners 286L and contact level dielectric layer 280, in accordance with some embodiments. FIG. 23 is a cross-sectional view of the GAA device 200 after depositing the conductive material layer 292.

The conductive material layer 292 is deposited in the gate via opening 282A, source/drain contact via opening 282B, and trench 284. The conductive material layer 292 may include a material the same as, or different from, the material providing the metal liner layer 286. In some embodiments, the conductive material layer 292 includes W, Mo, Ru, alloys thereof, the like, or combinations thereof. The conductive material layer 292 may be formed, for example, by CVD, PVD, or ALD. The deposition process is continued until the conductive material layer 292 fills the gate via opening 282A, source/drain contact via opening 282B, and trench 284 and extends above the contact level dielectric layer 280. In some embodiments, the conductive material layer 292 is formed with the metal having a grain size greater than the grain size of the metal in the metal liner layer 286.

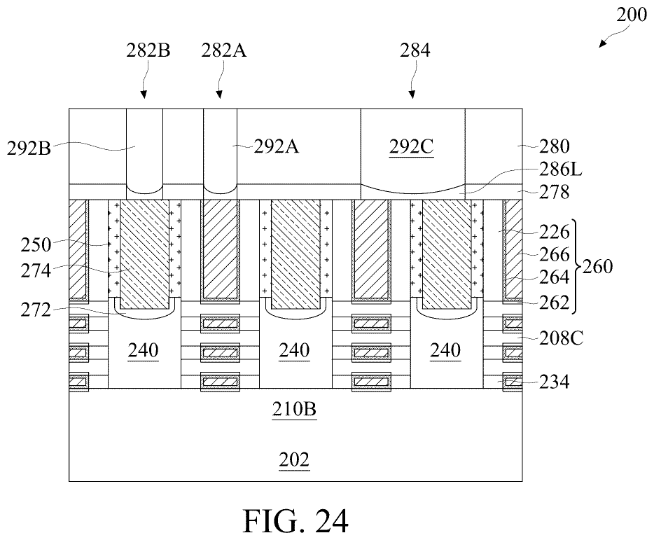

Referring to FIGS. 1 and 24, the method 100 proceeds to operation 144, where contact features 292A, 292B, and 292C are formed, in accordance with some embodiments.

FIG. 24 is a cross-sectional view of the GAA device 200 after forming the contact features 292A, 292B, and 292C, in accordance with some embodiments.

The contact features 292A, 292B, and 292C are formed by removing excess portions of the conductive material layer 292 outside of the gate via opening 282A, source/drain contact via opening 282B, and trench 284. In some embodiments, the excess conductive material over the top surface of the contact level dielectric layer 280 is removed by a planarization process, such as a CMP process. As a result, the top surfaces of the contact features 292A, 292B, and 292C are coplanar with the top surface of the contact level dielectric layer 280. The remaining portion of the conductive material layer 292 within the gate via opening 282A forms a gate via contact feature 292A for providing an electrical connection to the gate structure 260. Similarly, the remaining portion of the conductive material layer 292 within the source/drain contact via opening 282B forms a source/drain via contact feature 292B for providing an electrical connection to the source/drain feature 240 via a source/drain contact feature 274. Additionally, the remaining portion of the conductive material layer 292 within the trench 284 forms a gate-to-source/drain contact feature 292C, serving as a slot contact for interconnecting the gate structure 260 with an adjacent source/drain feature 240. In some embodiments, the gate via contact feature 292A and source/drain via contact feature 292B have heights ranging from 5 nm to 20 nm and lateral dimensions (i.e., widths) ranging from 5 nm to 100 nm.

In embodiments where the metal liners 286L and the contact features 292A-292C are made of the same metal, an interface forms between a metal liner 286L and a corresponding contact features 292A-292C due to difference in grain size-the metal in the metal liners 286L has a smaller grain size compared to the metal in the contact features 292A-292C.

In embodiments of the present disclosure, at the middle-of-line (MOL) contact level, the gate via contact feature 292A and the source/drain via contact feature 292B are formed of the same material. Consequently, the gate and source/drain via contact features 292A and 292B can be formed simultaneously without the need for separate masking steps. Compared to the existing technologies that require separate masking steps for forming the gate and source/drain via contact features with different metals, the present disclosure reduces mask usage, which helps to lower the manufacturing costs and improve yield.

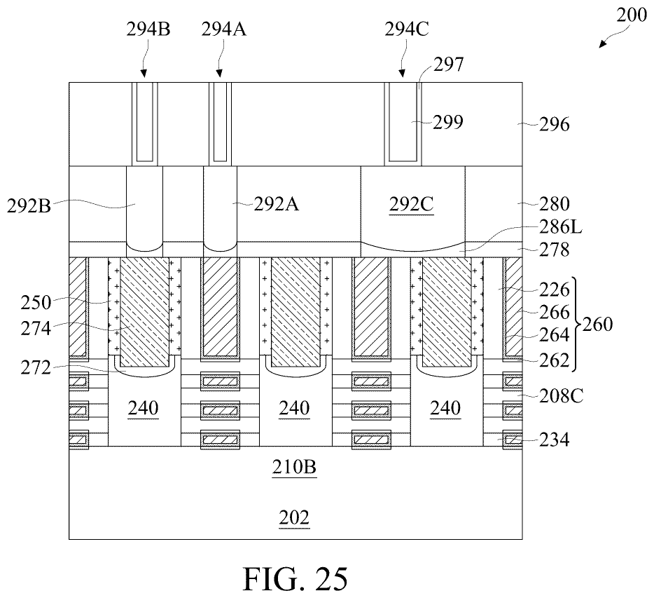

Referring to FIGS. 1 and 25, the method 100 proceeds to operation 146, where contact features 294A, 294B, and 294C are formed, in accordance with some embodiments.

FIG. 25 is a cross-sectional view of the GAA device 200 after forming contact features 294A, 294B and 294C, in accordance with some embodiments.

The contact features 294A, 294B and 294C are embedded in a contact level dielectric layer 296 and provide electric connections to the underlying contact features 292A, 292B and 292C, respectively. In some embodiments, each of the contact features 294A, 294B and 294C includes a diffusion barrier 297 and a conductive plug 299.

In some embodiments, the contact features 294A, 294B and 294C may be formed by first depositing the contact level dielectric layer 296 over the contact level dielectric layer 280. The contact level dielectric layer 296 includes a low-k dielectric material that is the same or different from the low-k dielectric material of the contact level dielectric layer 280. In some embodiments, the contact level dielectric layer 296 includes tetraethylorthosilicate (TEOS) formed oxide (e.g., reacting TEOS with oxygen using CVD to deposit silicon oxide), un-doped silicate glass, or doped silicon oxide such as borophosphosilicate glass (BPSG), fluoride-doped silica glass (FSG), phosphosilicate glass (PSG), boron doped silicon glass (BSG), other suitable low-k dielectric material, or combinations thereof. The contact level dielectric layer 296 may be formed by PECVD, FCVD, or other suitable deposition methods.

Subsequently, the contact level dielectric layer 296 is etched to form a plurality of openings (not shown) therein. In some embodiments, the plurality of openings includes a first opening exposing a top surface of the contact feature 292A, a second opening exposing a top surface of the contact feature 292B, and a third opening exposing a top surface of the contact feature 292C.

Next, a diffusion barrier layer (not shown) is conformally deposited along sidewalls and bottom surfaces of the openings and over a top surface of the contact level dielectric layer 296. In some embodiments, the diffusion barrier layer includes Ti, TiN, Ta, TaN, Ru, RuN, or other suitable diffusion barrier materials. In some embodiments, the diffusion barrier layer includes a stack of the above-mentioned diffusion barrier materials, such as, for example, Ti/TiN or Ta/TaN. In some embodiments, the diffusion barrier layer is deposited utilizing a conformal deposition process such as CVD, PECVD, PVD, or ALD.

Next, a conductive material layer (not shown) is deposited over the diffusion barrier layer to fill the openings. The conductive material layer may include Cu, Al, W, Co, an alloy thereof, or other suitable conductive metals. In some embodiments, the conductive material layer is deposited by a suitable deposition process such as, for example, CVD, PECVD, sputtering, or plating. The deposition process is continued until the conductive material layer fills the openings and extends above the contact level dielectric layer 296.

Next, portions of the conductive material layer and the diffusion barrier layer located above the contact level dielectric layer 296 are removed using a planarization process. In some embodiments, a CMP process is performed. After the planarization, a portion of the diffusion barrier layer remained in each of the openings constitutes the diffusion barrier 297, and a portion of the conductive material layer remained in each of the openings constitutes the conductive plug 299. The top surfaces of the contact features 294A, 294B, and 294C are coplanar with the top surface of the contact level dielectric layer 296.

One aspect of this description relates to a method for forming a semiconductor structure. The method includes forming a plurality of nanostructures; forming a gate structure on the nanostructures; forming a source/drain feature adjacent to the gate structure; forming a source/drain contact feature on the source/drain feature; forming a dielectric layer on the gate structure and the source/drain contact feature; etching the dielectric layer to form a first opening on the gate structure and a second opening on the source/drain contact feature; forming a metal liner layer in the first opening and the second opening; removing portions of the metal liner layer to form metal liners on bottoms of the first opening and the second opening; and depositing a conductive material layer on the metal liners to fill the first opening and the second opening and to form a first via contact feature in the first opening and a second via contact feature in the second opening.

Another aspect of this description relates to a method for forming a semiconductor structure. The method includes forming a vertical stack of nanostructures over a substrate; forming a gate structure surrounding and over the nanostructures; forming a source/drain feature over the substrate and adjacent to the nanostructures; forming a source/drain contact feature in contact with the source/drain feature, wherein the source/drain contact feature has a top surface coplanar with a top surface of the gate structure, and wherein the source/drain contact feature and the gate structure are laterally surrounded by a first dielectric layer; forming an etch stop layer over the first dielectric layer, the source/drain contact feature and the gate structure; forming a second dielectric layer over the etch stop layer; forming a first opening and a second opening extending through the second dielectric layer and the first dielectric layer, wherein the first opening exposes the gate structure and the second opening exposes the source/drain contact feature; forming metal liners solely on bottom surfaces of the first opening and the second opening; and forming a first via contact feature in the first opening to electrically couple to the gate structure and a second via contact feature in the second opening to electrically couple to the source/drain contact feature.

Still another aspect of this description relates to a semiconductor structure. The semiconductor structure includes a vertical stack of nanostructures over a substrate; a gate structure wrapping around the nanostructures; a source/drain feature abutting the nanostructures; a source/drain contact feature over the source/drain feature; an etch stop layer over the gate structure and the source/drain contact feature; a dielectric layer over the etch stop layer; a gate via contact feature extending through the dielectric layer and the etch stop layer and electrically coupled to the gate structure by way of a first metal liner; and a source/drain via contact feature extending through the dielectric layer and the etch stop layer and electrically coupled to the source/drain contact feature by way of a second metal liner. The dielectric layer contacts sidewalls of the gate via contact feature and the source/drain via contact feature, and the etch stop layer contacts sidewalls of the first metal liner and the second metal liner.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method for forming a semiconductor structure, comprising:
forming a plurality of nanostructures;
forming a gate structure on the nanostructures;
forming a source/drain feature adjacent to the gate structure;
forming a source/drain contact feature on the source/drain feature;
forming a dielectric layer on the gate structure and the source/drain contact feature;
etching the dielectric layer to form a first opening on the gate structure and a second opening on the source/drain contact feature;
forming a metal liner layer in the first opening and the second opening;
removing portions of the metal liner layer to form metal liners on bottoms of the first opening and the second opening; and
depositing a conductive material layer on the metal liners to fill the first opening and the second opening and to form a first via contact feature in the first opening and a second via contact feature in the second opening.

2. The method of claim 1, wherein the first via contact feature and the second via contact feature are laterally surrounded by the dielectric layer and have sidewalls contacting the dielectric layer and bottom surfaces contacting the metal liners.

3. The method of claim 1, wherein etching the dielectric layer to form the first opening on the gate structure and the second opening on the source/drain contact feature comprises:
forming a patterned photoresist layer over the dielectric layer; and
removing portions of the dielectric layer not covered by the patterned photoresist layer.

4. The method of claim 1, forming the metal liner layer in the first opening and the second opening comprises conformally depositing the metal liner layer along sidewalls and bottom surfaces of the first and second openings and over a top surface of the dielectric layer.

5. The method of claim 4, further comprising forming dielectric structures on the metal liner layer and fill the first opening and the second opening.

6. The method of claim 5, wherein the dielectric structures comprise a polymer containing carbon (C), hydrogen (H) and oxygen (O).

7. The method of claim 5, wherein removing the portions of the metal liner layer to form metal liners on the bottoms of the first opening and the second opening comprises:
recessing the dielectric structures to expose upper vertical portions of the metal liner layer on the sidewalls of the first opening and the second opening;
removing the metal liner layer from the top surface of the dielectric layer and the exposed upper vertical portions of the metal liner layer; and
removing remaining portions of the dielectric structures and remaining vertical portions of the metal liners, wherein horizontal portions of the metal liner layer remained on the bottoms of the first and second openings form the metal liners.

8. The method of claim 1, wherein the metal liner layer and the conductive material layer independently comprise tungsten (W), molybdenum (Mo) or Ruthenium (W).

9. The method of claim 1, wherein the metal liner layer has a grain size smaller than a grain size of the conductive material layer.

10. The method of claim 1, wherein the metal liners have planar or concave top surfaces.

11. A method for forming a semiconductor structure, comprising:
forming a vertical stack of nanostructures over a substrate;
forming a gate structure surrounding and over the nanostructures;
forming a source/drain feature over the substrate and adjacent to the nanostructures;
forming a source/drain contact feature in contact with the source/drain feature, wherein the source/drain contact feature has a top surface coplanar with a top surface of the gate structure, and wherein the source/drain contact feature and the gate structure are laterally surrounded by a first dielectric layer;
forming an etch stop layer over the first dielectric layer, the source/drain contact feature and the gate structure;
forming a second dielectric layer over the etch stop layer;
forming a first opening and a second opening extending through the second dielectric layer and the first dielectric layer, wherein the first opening exposes the gate structure and the second opening exposes the source/drain contact feature;
forming metal liners solely on bottom surfaces of the first opening and the second opening; and
forming a first via contact feature in the first opening to electrically couple to the gate structure and a second via contact feature in the second opening to electrically couple to the source/drain contact feature.

12. The method of claim 11, further comprising forming a silicide feature between the source/drain feature and the source/drain contact feature.

13. The method of claim 11, wherein forming the metal liners comprises:
depositing a metal liner layer along sidewalls and bottom surfaces of the first and second openings and over the second dielectric layer;
forming a first dielectric structure over the metal liner layer and filling the first opening and a second dielectric structure over the metal liner layer to fill the second opening;
recessing the first dielectric structure and the second dielectric structure to expose upper vertical portions of the metal liner layer in each of the first opening and the second opening;
removing the metal liner layer from the top surface of the second dielectric layer and from upper sidewalls of each of the first opening and the second opening; and
removing the remaining vertical portions of the metal liner layer and the remaining portion of each of the first and second dielectric features.

14. The method of claim 13, wherein recessing the first dielectric structure and the second dielectric structure comprises performing an etching process using an etching gas comprising F.

15. The method of claim 13, wherein removing the remaining vertical portions of the metal liner layer and the remaining portion of each of the first and second dielectric features comprising performing an etching process using an etching gas comprising chlorine (Cl) and oxygen (O).

16. A semiconductor structure, comprising:
a vertical stack of nanostructures over a substrate;
a gate structure wrapping around the nanostructures;
a source/drain feature abutting the nanostructures;
a source/drain contact feature over the source/drain feature;
an etch stop layer over the gate structure and the source/drain contact feature;
a dielectric layer over the etch stop layer;
a gate via contact feature extending through the dielectric layer and the etch stop layer and electrically coupled to the gate structure by way of a first metal liner; and
a source/drain via contact feature extending through the dielectric layer and the etch stop layer and electrically coupled to the source/drain contact feature by way of a second metal liner,
wherein the dielectric layer contacts sidewalls of the gate via contact feature and the source/drain via contact feature, and the etch stop layer contacts sidewalls of the first metal liner and the second metal liner.

17. The semiconductor structure of claim 16, wherein the gate via contact feature and the source/drain via contact feature are composed of the same metal.

18. The semiconductor structure of claim 16, wherein the first metal liner and the second metal liner have top surfaces above, coplanar with, or below a top surface of the etch stop layer.

19. The semiconductor structure of claim 16, the first metal liner and the second metal liner have concave top surfaces.

20. The semiconductor structure of claim 16, wherein the first metal liner has a grain size smaller than a grain size of the gate via contact feature, and the second metal liner has a grain size smaller than a grain size of the source/drain via contact feature.
